(19) United States
(12) Patent Application Publication
(10) Pub. No.: US 2024/0364301 A1
(43) Pub. Date: Oct. 31, 2024

(54) ACOUSTIC WAVE ELEMENT, ACOUSTIC WAVE FILTER DEVICE, AND MULTIPLEXER

(71) Applicant: Murata Manufacturing Co., Ltd., Nagaokakyo-shi (JP)

(72) Inventor: Yohei KONAKA, Nagaokakyo-shi (JP)

(21) Appl. No.: 18/632,349

(22) Filed: Apr. 11, 2024

(30) Foreign Application Priority Data
Apr. 26, 2023 (JP) 2023-072493

(51) Int. Cl. H03H 9/02; H03H 9/64; H03H 9/70

(52) U.S. Cl. CPC H03H 9/02275; H03H 9/02984; H03H 9/02992; H03H 9/703; H03H 9/6406

(57) ABSTRACT

An acoustic wave element includes IDT electrodes on two main surfaces of a piezoelectric layer, and reflectors on both of the two main surfaces. The IDT electrodes each include electrode fingers extending in a second direction that intersects a first direction. The reflectors each include reflection electrode fingers extending in the second direction. An array pitch of the electrode fingers along the first direction is Pi, an array pitch of the reflection electrode fingers is Pr, and an IDT-reflector gap in the first direction d1 between a center of an electrode finger and a center of a reflection electrode finger that is closest to the IDT electrode among the plurality of reflection electrode fingers is G, a thickness of the piezoelectric layer is smaller than or equal to twice Pi, G is smaller than Pr, and Pr is greater than Pi.

### CROSS REFERENCE TO RELATED APPLICATIONS

This application claims the benefit of priority to Japanese Patent Application No. 2023-072493, filed on Apr. 26, 2023. The entire contents of this application are hereby incorporated herein by reference.

### BACKGROUND OF THE INVENTION

### 1. Field of the Invention

The present invention relates to acoustic wave elements, acoustic wave filter devices, and multiplexers.

### 2. Description of the Related Art

In recent years, to increase data transfer speed of mobile phones, multi-band systems have been used. Since transmission and reception using multiple frequency bands may be performed, multiple filter devices that allow high frequency signals of different frequency bands to pass therethrough are arranged in a front end circuit of a mobile phone. In this case, high isolation between bands adjacent to each other and low-loss characteristics of pass bands are required for the multiple filter devices.

In Japanese Unexamined Patent Application Publication No. 2021-44835, a waveguide device that confines acoustic waves within a part of the structure inside a piezoelectric layer is disclosed, and an acoustic wave resonator including a piezoelectric layer, an IDT electrode formed on an upper surface of the piezoelectric layer, and an IDT electrode formed on a lower surface of the piezoelectric layer is disclosed as an example of the waveguide device.

In the acoustic wave resonator described in Japanese Unexamined Patent Application Publication No. 2021-44835, reflection inside the IDT electrode is high. Thus, there is such a problem that bandpass characteristics deteriorate due to the impact of a spurious wave generated at a frequency lower than a resonant frequency of a surface acoustic wave resonator.

### SUMMARY OF THE INVENTION

Example embodiments of the present invention provide acoustic wave elements, acoustic wave filter devices, and multiplexers each able to reduce or prevent an increase of return loss at a frequency lower than a resonant frequency of an acoustic wave resonator.

An acoustic wave element according to an example embodiment of the present invention includes a piezoelectric layer, interdigital transducer (IDT) electrodes that are provided on two main surfaces of the piezoelectric layer, and a plurality of reflectors that are provided on both of the two main surfaces. The IDT electrodes each include a pair of comb-shaped electrodes that are opposite to each other. Each of the comb-shaped electrodes defining the pair of comb-shaped electrodes includes a plurality of electrode fingers that are arranged to extend in a second direction that intersects a first direction in a direction along a main surface of the piezoelectric layer, and a busbar electrode that connects one ends of the plurality of electrode fingers. The plurality of reflectors are arranged on two outer sides of the IDT electrode in the first direction and each include a plurality of reflection electrode fingers that are arranged to extend in the second direction. In a case where an array pitch of the plurality of along the first direction electrode fingers arranged is represented by Pi, an array pitch of the plurality of reflection electrode fingers arranged along the first direction is represented by Pr, and an IDT-reflector gap that is a distance in the first direction between a center of an electrode finger that is closest to the reflector among the plurality of electrode fingers and a center of a reflection electrode finger that is closest to the IDT electrode among the plurality of reflection electrode fingers is represented by G, a thickness of the piezoelectric layer is smaller than or equal to a value that is twice Pi, G is smaller than Pr, and Pr is greater than Pi.

An acoustic wave filter device according to an example embodiment of the present invention includes an acoustic wave element according to an example embodiment of the present invention.

A multiplexer according to an example embodiment of the present invention includes a plurality of filters including an acoustic wave filter device according to an example embodiment of the present invention. One of input/output terminals of the plurality of filters is connected directly or indirectly to a common terminal. At least one of the plurality of filters except the acoustic wave filter device has a pass band whose frequencies are lower than frequencies of a pass band of the acoustic wave filter device.

With acoustic wave elements, acoustic wave filter devices, and multiplexers according to example embodiments of the present invention, an increase of return loss at a frequency lower than a resonant frequency of the acoustic wave element is able to be reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a diagram of a first IDT electrode and first reflectors of an acoustic wave element according to a first example embodiment of the present invention when seen from above.

FIG. 1B is a diagram of a second IDT electrode and second reflectors of the acoustic wave element according to the first example embodiment of the present invention.

FIG. 2 is an enlarged view of a cross-section of the acoustic wave element taken along line II-II in FIGS. 1A and 1B.

FIG. 3 is an enlarged view of a cross-section of the acoustic wave element taken along line III-III in FIGS. 1A and 1B.

FIG. 4 is a diagram illustrating an IDT wave length, a reflector wave length, and an IDT-reflector gap in the acoustic wave element.

FIG. 5 is a graph indicating impedance characteristics of acoustic wave elements according to Example 1 and Comparative Example.

FIG. 6 is a graph indicating reflection characteristics of the acoustic wave elements according to Example 1 and Comparative Example.

FIG. 7 is a graph indicating impedance characteristics of acoustic wave elements according to Example 1, Example 2, and Example 3.

FIG. 8 is a graph indicating reflection characteristics of the acoustic wave elements according to Example 1, Example 2, and Example 3.

FIG. 9 is a graph indicating impedance characteristics of acoustic wave elements according to Example 1, Example 4, and Example 5.

FIG. 10 is a graph indicating reflection characteristics of the acoustic wave elements according to Example 1, Example 4, and Example 5.

FIG. 11 includes graphs indicating reflection characteristics of an acoustic wave element in the case where IDT-reflector gap/reflector wave length is changed.

FIG. 12 includes graphs indicating reflection characteristics of an acoustic wave element in the case where reflector wave length/IDT wave length is changed.

FIG. 13 includes graphs indicating reflection characteristics of an acoustic wave element in the case where reflector wave length/IDT wave length is changed.

FIG. 14 includes graphs indicating reflection characteristics of an acoustic wave element in the case where IDT-reflector gap/reflector wave length and reflector wave length/IDT wave length are changed.

FIG. 15 is a diagram illustrating the range of band width in which spurious wave generation is improved.

FIG. 16 is a graph indicating the relationship between IDT-reflector gap/reflector wave length and the band width of a region where return loss is reduced.

FIG. 17 is a diagram illustrating a circuit configuration of an acoustic wave filter device according to a second example embodiment of the present invention.

FIG. 18 is a circuit configuration diagram of a multiplexer according to a third example embodiment of the present invention and a peripheral circuit thereof.

### DETAILED DESCRIPTION OF THE EXAMPLE EMBODIMENTS

Hereinafter, example embodiments of the present invention will be described in detail with reference to tables and drawings. The example embodiments described below each illustrate a comprehensive or specific example. The numerical values, shapes, materials, component elements, arrangements of the component elements, manners in which the component elements are connected, and so on illustrated in the example embodiments described below are merely examples and are not intended to limit the present invention. Among the component elements in the example embodiments described below, component elements that are not described in independent claims are described as arbitrary component elements. In addition, the sizes of or the size ratios between the component elements illustrated in the drawings are not necessarily precise.

### First Example Embodiment

### Structure of Surface Acoustic Wave Resonator

A structure of an acoustic wave element 10 according to a first example embodiment of the present invention will be described.

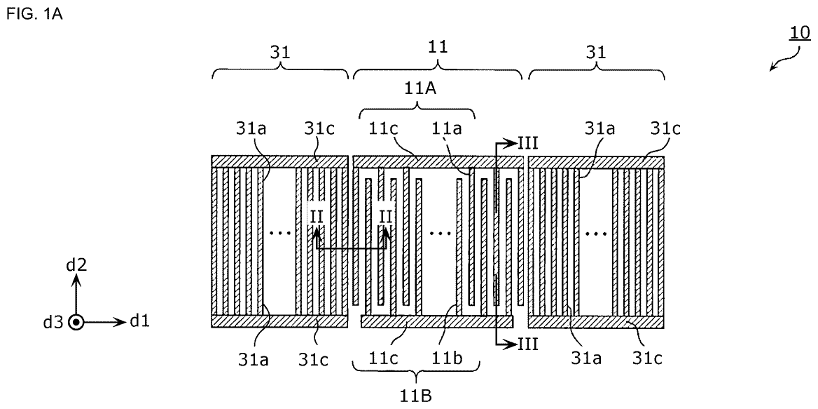

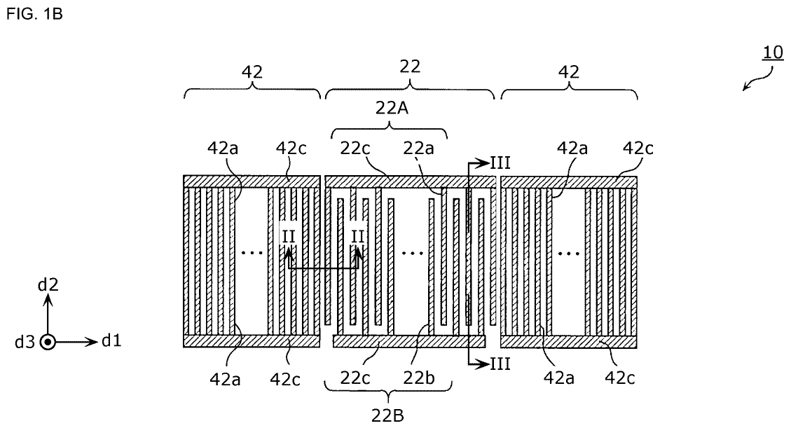

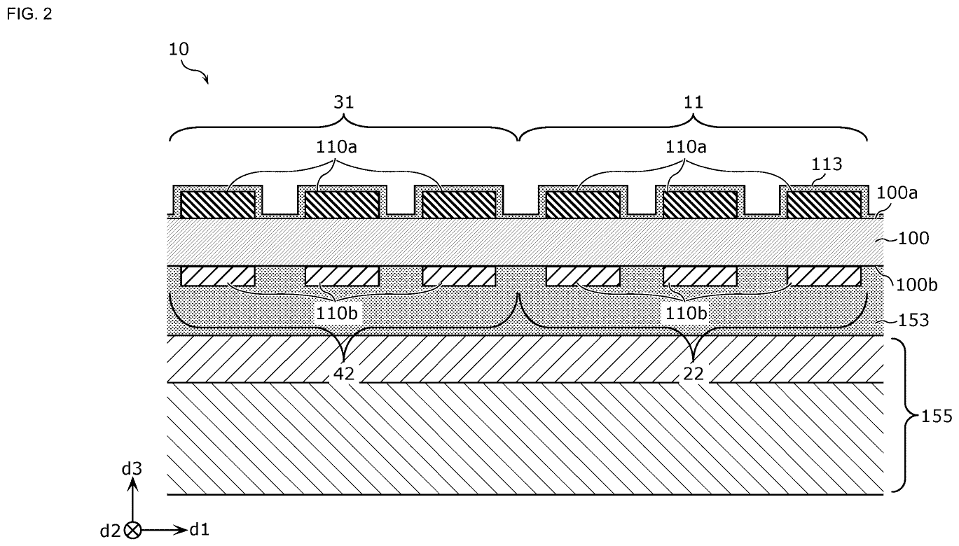

FIG. 1A is a diagram of a first IDT electrode 11 and first reflectors 31 of the acoustic wave element 10 according to the first example embodiment when seen from above. FIG. 1B is a diagram of a second IDT electrode 22 and second reflectors 42 of the acoustic wave element 10 when seen from above. FIG. 2 is an enlarged view of a cross-section of the acoustic wave element 10 taken along line II-II in FIGS. 1A and 1B.

The acoustic wave element 10 illustrated in FIGS. 1A, 1B, and 2 is preferably a single-port surface acoustic wave (SAW) resonator including a piezoelectric layer 100, a plurality of IDT (InterDigital Transducer) electrodes, and a plurality of reflectors.

The piezoelectric layer 100 illustrated in FIG. 2 is preferably made of, for example, 0° Y-cut X-propagating LiNbO₃ piezoelectric single crystal or piezoelectric ceramics (lithium niobate single crystal or ceramics that is cut along a plane whose normal is defined by an axis rotated by 0° in a Z-axis direction from a Y-axis around an X-axis, surface acoustic waves propagating in the X-axis direction in the single crystal or ceramics).

The piezoelectric layer 100 includes a first main surface 100a and a second main surface 100b. The first main surface 100a and the second main surface 100b, which are both main surfaces of the piezoelectric layer 100, are opposite to each other. The thickness of the piezoelectric layer 100 is smaller than or equal to an IDT wave length (λ_{IDT}), which will be described later.

The plurality of IDT electrodes include the first IDT electrode 11 and the second IDT electrode 22. The first IDT electrode 11 is provided on the first main surface 100a of the piezoelectric layer 100, and the second IDT electrode 22 is provided on the second main surface 100b of the piezoelectric layer 100. That is, the IDT electrodes are provided on both of the main surfaces of the piezoelectric layer 100.

The plurality of reflectors include a plurality of first reflectors 31 and a plurality of second reflectors 42. The plurality of first reflectors 31 are provided on the first main surface 100a of the piezoelectric layer 100, and the plurality of second reflectors 42 are provided on the second main surface 100b of the piezoelectric layer 100. In the present example embodiment, the first and second reflectors are provided on the corresponding main surfaces of the piezoelectric layer 100.

In FIGS. 1A and 1B, perspective views of an IDT electrode and reflectors seen from a direction perpendicular or substantially perpendicular to a main surface of the piezoelectric layer 100 are illustrated. As illustrated in FIG. 1A, electrodes of the first reflectors 31 are arranged on two outer sides of the first IDT electrode 11 in a first direction d1, which is an acoustic wave propagating direction. As illustrated in FIG. 1B, electrodes of the second reflectors 42 are arranged on both outer sides of the second IDT electrode 22 in the first direction d1.

As illustrated in FIG. 2, the acoustic wave element 10 includes the piezoelectric layer 100 and electrode layers 110a and 110b that define IDT electrodes and reflector electrodes.

The electrode layers 110a and 110b have a multilayer structure including multiple metals that are laminated. For example, the electrode layer 110a defining the first IDT electrode 11 and the first reflectors 31 has a multilayer structure in which Ti, AlCu (for example, Al including about 1% of Cu), and Ti are laminated in this order. The electrode layer 110b defining the second IDT electrode 22 and the second reflectors 42 has a multilayer structure in which, for example, Ti, Pt, and Ti are laminated in this order. In the present example embodiment, the thickness of the electrode layer 110b is smaller than the thickness of the electrode layer 110a. Furthermore, the density of the electrode layer 110b is higher than the density of the electrode layer 110a.

Materials making the electrode layers 110a and 110b are not limited to the materials described above. Furthermore, the electrode layers 110a and 110b do not necessarily have the multilayer structure described above. For example, each of the electrode layers 110a and 110b may preferably include metal such as Ti, Al, Cu, Pt, Au, Ag, or Pd or an alloy of the metals described above or may include a multilayer body made of metals or alloys of the metals described above. Ti included in the electrode layers 110a and 110b improves characteristics of close contact with other layers.

Furthermore, the acoustic wave element 10 includes a protection film 113 provided on the first main surface 100a side and a low acoustic velocity layer 153 and a high acoustic velocity support substrate 155 that are provided on the second main surface 100b side.

The protection film 113 is provided on the first main surface 100a of the piezoelectric layer 100 in such a manner that the protection film 113 covers the electrode layer 110a. The protection film 113 is a layer provided for the purpose of protecting the electrode layer 110a from external environment, adjusting frequency-temperature characteristics, increasing moisture resistance, and so on. The protection film 113 is, for example, a film including silicon dioxide (SiO₂) as a main component. The protection film 113 is not necessarily provided.

The low acoustic velocity layer 153 is provided on the second main surface 100b of the piezoelectric layer 100 in such a manner that the low acoustic velocity layer 153 covers the electrode layer 110b. The electrode layer 110b forming the second IDT electrode 22 and the second reflectors 42 are embedded in the low acoustic velocity layer 153. The low acoustic velocity layer 153 is a film in which bulk waves propagate at an acoustic velocity lower than the acoustic velocity of acoustic waves propagating in the piezoelectric layer 100 and is located between the piezoelectric layer 100 and the high acoustic velocity support substrate 155. With this structure and characteristics of acoustic waves whose energy is intrinsically concentrated on a medium low acoustic velocity, leakage of surface acoustic wave energy to the outside of an IDT electrode can be reduced or prevented. For example, the low acoustic velocity layer 153 is a film including silicon dioxide (SiO₂) as a main component.

The low acoustic velocity layer 153 may be made of, for example, a dielectric such as glass, silicon oxide, silicon oxynitride, lithium oxide, tantalum oxide, a compound obtained by adding fluorine, carbon, or boron to silicon oxide, or a material including a material described above as a main component.

The high acoustic velocity support substrate 155 is a substrate that supports the low acoustic velocity layer 153, the piezoelectric layer 100, and the electrode layers 110a and 110b. The high acoustic velocity support substrate 155 is a substrate in which bulk waves propagate at an acoustic velocity higher than an acoustic velocity of surface acoustic waves or boundary acoustic waves propagating in the piezoelectric layer 100. The high acoustic velocity support substrate 155 defines and functions to confine surface acoustic waves in a portion where the piezoelectric layer 100 and the low acoustic velocity layer 153 are laminated so that the surface acoustic waves do not leak below the high acoustic velocity support substrate 155. For example, the high acoustic velocity support substrate 155 is a silicon substrate.

The high acoustic velocity support substrate 155 may be made of, for example, a piezoelectric material such as aluminum nitride, lithium tantalate, lithium niobate, or quartz, ceramic such as alumina, sapphire, magnesia, silicon nitride, silicon carbide, zirconia, cordierite, mullite, steatite, forsterite, spinel, or Sialon, a dielectric such as aluminum oxide, silicon oxynitride, DLC (diamond-like carbon), or diamond, a semiconductor such as silicon, or a material including a material described above as a main component. The spinel described above includes, for example, an aluminum compound including one or more elements selected from Mg, Fe, Zn, Mn, and the like and oxygen. The spinel described above is preferably, for example, MgAl₂O₄, FeAl₂O₄, ZnAl₂O₄, or MnAl₂O₄.

The high acoustic velocity support substrate 155 may have a structure in which a support substrate and a high acoustic velocity layer in which bulk waves propagate at an acoustic velocity higher than an acoustic velocity of surface acoustic waves or boundary acoustic waves propagating in the piezoelectric layer 100 are laminated.

In this case, the support substrate may be made of, for example, a piezoelectric material such as aluminum nitride, lithium tantalate, lithium niobate, or quartz, ceramic such as alumina, sapphire, magnesia, silicon nitride, silicon carbide, zirconia, cordierite, mullite, steatite, or forsterite, a dielectric such as diamond or glass, a semiconductor such as silicon or gallium nitride, resin, or a material including a material described above as a main component. Furthermore, the high acoustic velocity layer may be made of various high acoustic velocity materials such as, for example, aluminum nitride, aluminum oxide, silicon carbide, silicon nitride, silicon oxynitride, a DLC film, diamond, a medium including a material described above as a main component, or a medium including a mixture of materials described above as a main component.

With the multilayer structure of the piezoelectric layer 100, a Q value of an acoustic wave resonator at a resonant frequency and an anti-resonant frequency can be significantly increased compared to a structure in which a piezoelectric layer is a single layer. That is, since a surface acoustic wave resonator with a high Q value can be configured, a filter with a low insertion loss including the surface acoustic wave resonator can be configured.

Furthermore, since the second IDT electrode 22 is embedded in the low acoustic velocity layer 153, a portion of the piezoelectric layer 100 where acoustic waves are excited is also supported by the low acoustic velocity layer 153. Thus, the shape of the piezoelectric layer 100 is less likely to be changed, and fluctuations in electrical characteristics can be reduced or prevented or minimized. Furthermore, since the second IDT electrode 22 is embedded in the low acoustic velocity layer 153, a higher-order mode can be made to leak to the low acoustic velocity layer 153 side. Thus, generation of a higher-order mode can be reduced or prevented.

As illustrated in FIG. 1A, the first IDT electrode 11 preferably includes a pair of comb-shaped electrodes 11A and 11B that are opposite to each other. The comb-shaped electrode 11A includes a plurality of electrode fingers 11a that are arranged to extend in a second direction d2 that intersects the first direction d1 in a direction along a main surface of the piezoelectric layer 100 and a busbar electrode 11c that connects one ends of the plurality of electrode fingers 11a. The comb-shaped electrode 11B includes a plurality of electrode fingers 11b that are arranged to extend in the second direction d2 and a busbar electrode 11c that connects single ends of the plurality of electrode fingers 11b. The plurality of electrode fingers 11a and 11b are arranged with a predetermined pitch along the first direction d1.

The first reflectors 31 are arranged adjacent to the first IDT electrode 11 in the first direction d1. The first reflectors 31 each include a plurality of reflection electrode fingers 31a that are arranged to extend in the second direction d2 and a busbar electrode 31c that connects one ends of the plurality of reflection electrode fingers 31a. The plurality of reflection electrode fingers a 31a are arranged with predetermined pitch along the first direction d1.

The second IDT electrode 22 and the second reflectors 42 preferably have configurations the same as or similar to the configurations of the first IDT electrode 11 and the first reflectors 31, respectively.

As illustrated in FIG. 1B, the second IDT electrode 22 includes a pair of comb-shaped electrodes 22A and 22B that are opposite to each other. The comb-shaped electrode 22A includes a plurality of electrode fingers 22a that are arranged to extend in the second direction d2 and a busbar electrode 22c that connects single ends of the plurality of electrode fingers 22a. The comb-shaped electrode 22B includes a plurality of electrode fingers 22b that are arranged to extend in the second direction d2 and a busbar electrode 22c that connects one ends of the plurality of electrode fingers 22b. The plurality of electrode fingers 22a and 22b are arranged with a predetermined pitch along the first direction d1.

The second reflectors 42 are arranged adjacent to the second IDT electrode 22 in the first direction d1. The second reflectors 42 each include a plurality of reflection electrode fingers 42a that are arranged to extend in the second direction d2 and a busbar electrode 42c that connects one ends of the plurality of reflection electrode fingers 42a. The plurality of reflection electrode fingers 42a are arranged with a predetermined pitch along the first direction d1.

The electrode fingers 11a and 22a that are aligned vertically to sandwich the piezoelectric layer 100 therebetween preferably have the same polarity, and the electrode fingers 11b and 22b that are aligned vertically preferably have the same polarity.

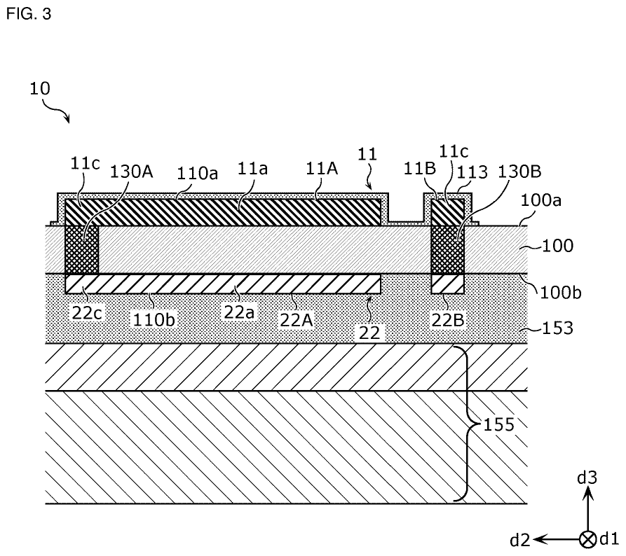

FIG. 3 is an enlarged view of a cross-section of the acoustic wave element 10 taken along line III-III in FIGS. 1A and 1B.

As illustrated in FIG. 3, the first IDT electrode 11 and the second IDT electrode 22 of the acoustic wave element 10 are connected to each other.

For example, the comb-shaped electrode 11A included in the first IDT electrode 11 and the comb-shaped electrode 22A included in the second IDT electrode 22 are electrically connected. Specifically, the busbar electrode 11c of the comb-shaped electrode 11A and the busbar electrode 22c of the comb-shaped electrode 22A are connected by a through conductor 130A that penetrates through the piezoelectric layer 100 in the thickness direction of the piezoelectric layer 100.

Furthermore, the comb-shaped electrode 11B included in the first IDT electrode 11 and the comb-shaped electrode 22B included in the second IDT electrode 22 are preferably electrically connected. Specifically, the busbar electrode 11c of the comb-shaped electrode 11B and the busbar electrode 22c of the comb-shaped electrode 22B are connected by a through conductor 130B that penetrates through the piezoelectric layer 100 in the thickness direction of the piezoelectric layer 100.

Portions of two comb-shaped electrodes, which are aligned vertically to sandwich the piezoelectric layer 100 therebetween, where busbar electrodes are provided may be electrically connected or lead wires connected to the busbar electrodes may be electrically connected. Furthermore, although the first reflectors 31 and the second reflectors 42, which are aligned vertically to sandwich the piezoelectric layer 100 therebetween, are not connected by through conductors or other elements, both the first reflectors 31 and the second reflectors 42 may be set at a reference potential (ground).

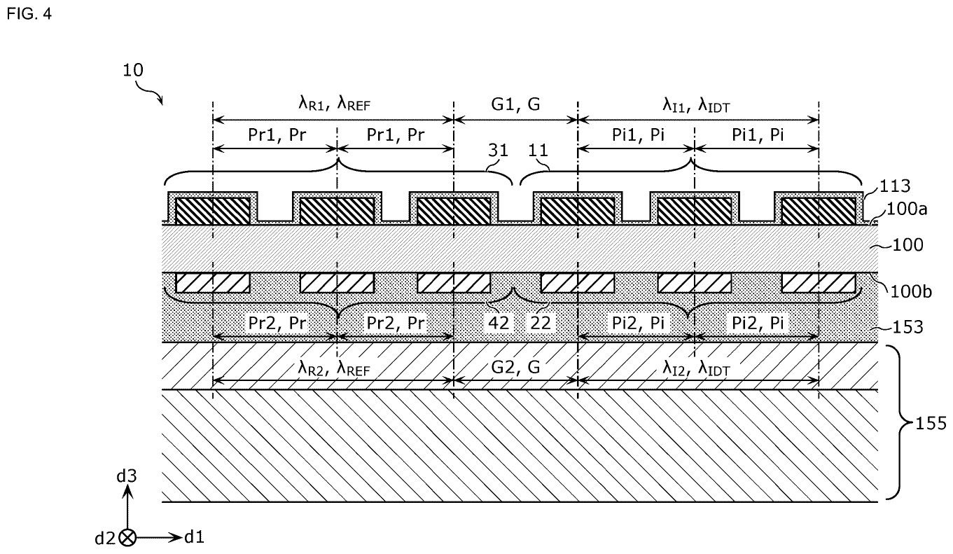

FIG. 4 is a diagram illustrating an IDT wave length, a reflector wave length, and an IDT-reflector gap in the acoustic wave element 10.

In FIG. 4, each of the repetition pitch of the plurality of electrode fingers 11a defining the comb-shaped electrode 11A and the repetition pitch of the plurality of electrode fingers 11b defining the comb-shaped electrode 11B is defined by an IDT wave length (λ_{I1}).

Furthermore, each of the repetition pitch of the plurality of electrode fingers 22a defining the comb-shaped electrode 22A and the repetition pitch of the plurality of electrode fingers 22b defining the comb-shaped electrode 22B is defined by an IDT wave length (λ_{I2}).

In the present example embodiment, since all λ_{I1}, λ_{I2}, and λ_{IDT} are equal or substantially equal, each of the IDT wave length λ_{I1} and the IDT wave length λ_{I2} will be referred to as an IDT wave length (λ_{IDT}).

Furthermore, a value that is about twice the repetition pitch of the plurality of reflection electrode fingers 31a defining the first reflectors 31 is defined by a reflector wave length (λ_{R1}).

Furthermore, a value that is about twice the repetition pitch of the plurality of reflection electrode fingers 42a defining the second reflectors 42 is defined by a reflector wave length (λ_{R2}).

Hereinafter, in the case where λ_{R1} is equal or substantially equal to λ_{R2}, each of the reflector wave length λ_{R1} and the reflector wave length λ_{R2} will be referred to as a reflector wave length (λ_{REF}).

Furthermore, an IDT-reflector gap that is the distance in the first direction d1 between the center of an electrode finger that is closest to a first reflector 31 among the plurality of electrode fingers 11a and the center of a reflection electrode finger that is closest to the first IDT electrode 11 among the plurality of reflection electrode fingers 31a is defined by G1.

Furthermore, an IDT-reflector gap that is the distance in the first direction d1 between the center of an electrode finger that is closest to a second reflector 42 among the plurality of electrode fingers 22a and the center of a reflection electrode finger that is closest to the second IDT electrode 22 among the plurality of reflection electrode fingers 42a is defined by G2.

Hereinafter, in the case where G1 is equal or substantially equal to G2, each of the IDT-reflector gap G1 and the IDT-reflector gap G2 will be referred to as an IDT-reflector gap G.

Under the above definitions, for example, the acoustic wave element 10 according to the present example embodiment is preferably defined by the following relationship: the thickness of the piezoelectric layer 100 is smaller than or equal to the IDT wave length (λ_{IDT}), the value of the IDT-reflector gap G is smaller than a value that is about 0.5 times the reflector wave length (λ_{REF}), and the reflector wave length (λ_{REF}) is greater than the IDT wave length (λ_{IDT}).

With the acoustic wave element 10 satisfying the above relationship, an increase of return loss at a frequency lower than the resonant frequency of the acoustic wave element 10 can be reduced or prevented.

The above relationship regarding the wave lengths is expressed using array pitches that are about half the wave lengths, as described below.

In FIG. 4, an array pitch of the plurality of electrode fingers 11a and 11b that are arranged along the first direction d1 will be represented by Pi1, and an array pitch of the plurality of electrode fingers 22a and 22b will be represented by Pi2. In the present example embodiment, since Pi1 is equal or substantially equal to Pi2, each of the array pitch Pi1 and the array pitch Pi2 will be referred to as an array pitch Pi.

Furthermore, an array pitch of the plurality of reflection electrode fingers 31a that are arranged along the first direction d1 will be represented by Pr1, and an array pitch of the plurality of reflection electrode fingers 42a will be represented by Pr2. Hereinafter, in the case where Pr1 is equal or substantially equal to Pr2, each of the array pitch Pr1 and the array pitch Pr2 will be referred to as an array pitch Pr.

Under the above definitions, for example, the acoustic wave element 10 according to the present example embodiment is preferably defined by the following relationship: the thickness of the piezoelectric layer 100 is smaller than or equal to a value that is twice the array pitch Pi, the IDT-reflector gap G is smaller than the array pitch Pr (G<Pr), and the array pitch Pr is greater than the array pitch Pi (Pr>Pi).

With the acoustic wave element 10 satisfying the above relationship, an increase of return loss at a frequency lower than the resonant frequency of the acoustic wave element 10 can be reduced or prevented. Reflection characteristics and other characteristics of an acoustic wave element will be described below.

Return Characteristics and Other Characteristics of Acoustic Wave Elements according to Example 1 and Comparative Example

An acoustic wave element according to Example 1, which is an example of an example embodiment, and an acoustic wave element according to Comparative Example will be described.

The acoustic wave element 10 according to Example 1 includes the piezoelectric layer 100, the first IDT electrode 11, the first reflectors 31, the second IDT electrode 22, the second reflectors 42, the protection film 113, the low acoustic velocity layer 153, and the high acoustic velocity support substrate 155. The acoustic wave element according to Comparative Example includes similar component elements.

When the acoustic wave element 10 according to Example 1 is seen from a direction perpendicular or substantially perpendicular to a main surface of the piezoelectric layer 100, the first IDT electrode 11 and the second IDT electrode 22 are arranged at the same or substantially the same position and the first reflectors 31 and the second reflectors 42 are arranged at the same or substantially the same position. In other words, when the acoustic wave element 10 is seen from a third direction d3, which is orthogonal or substantially orthogonal to both the first direction d1 and the second direction d2, the first IDT electrode 11 and the second IDT electrode 22 overlap and the first reflectors 31 and the second reflectors 42 overlap. The acoustic wave element according to Comparative Example is arranged in a similar manner.

In the acoustic wave element 10 according to Example 1, the piezoelectric layer 100 is made of LiTaO₃, and the piezoelectric layer 100 has a thickness of about 0.2λ_{IDT}. The first IDT electrode 11 has a multilayer structure including a Ti layer, an AlCu layer, and a Ti layer, and the Ti layer, the AlCu layer, and the Ti layer have thicknesses of about 0.002λ_{IDT}, about 0.07λ_{IDT}, and about 0.006λ_{IDT}, respectively. The second IDT electrode 22 has a multilayer structure including a Ti layer, a Pt layer, and a Ti layer, and the Ti layer, the Pt layer, and the Ti layer have thicknesses of about 0.003λ_{IDT}, about 0.013λ_{IDT}, and about 0.002λ_{IDT}, respectively. The protection film 113 is made of SiO₂, and the protection film 113 has a thickness of about 0.015λ_{IDT}. The low acoustic velocity layer 153 is made of SiO₂, and the low acoustic velocity layer 153 has a thickness of about 0.218λ_{IDT}. The thickness of the low acoustic velocity layer 153 is the thickness of a portion of the low acoustic velocity layer 153 where the electrode fingers 22a and 22b of the second IDT electrode 22 are not provided, that is, a portion that is in contact with the second main surface 100b. The high acoustic velocity support substrate 155 is made of an Si substrate and SiN provided on the Si substrate. The high acoustic velocity support substrate 155 has a thickness of about 0.45λ_{IDT}. The acoustic wave element according to Comparative Example is formed in a similar manner.

Table 1 indicates electrode parameters of the acoustic wave elements according to Example 1 and Comparative Example.

TABLE 1

| | | Comparative |
|---|---|---|
| | Example 1 | Example |
| λ_{REF}/λ_{IDT} | 1.06 | 1.00 |
| Pr/Pi | 1.06 | 1.00 |
| Number of IDT pairs | 80 | 80 |
| (pairs) | | |
| Intersecting width | 75.2 | 75.2 |
| (μm) | | |
| Number of REF pairs (pairs) | 10 | 10 |
| G/λ_{REF} | 0.40 | 0.50 |
| G/Pr | 0.80 | 1.00 |

As indicated in Table 1, while the value of the IDT-reflector gap G of the acoustic wave element according to Comparative Example is about 0.5 times the reflector wave length (λ_{REF}), the value of the IDT-reflector gap G of the acoustic wave element according to Example 1 is about 0.4 times the reflector wave length (λ_{REF}). Furthermore, while the reflector wave length (λ_{REF}) is equal or substantially equal to the IDT wave length (λ_{IDT}) in the acoustic wave element according to Comparative Example, the reflector wave length (λ_{REF}) is about 1.06 times the IDT wave length (λ_{IDT}) in the acoustic wave element according to Example 1. That is, in Example 1, the value of the IDT-reflector gap G is about 0.4 times the reflector wave length (λ_{REF}) and the reflector wave length (λ_{REF}) is greater than the IDT wave length (λ_{IDT}).

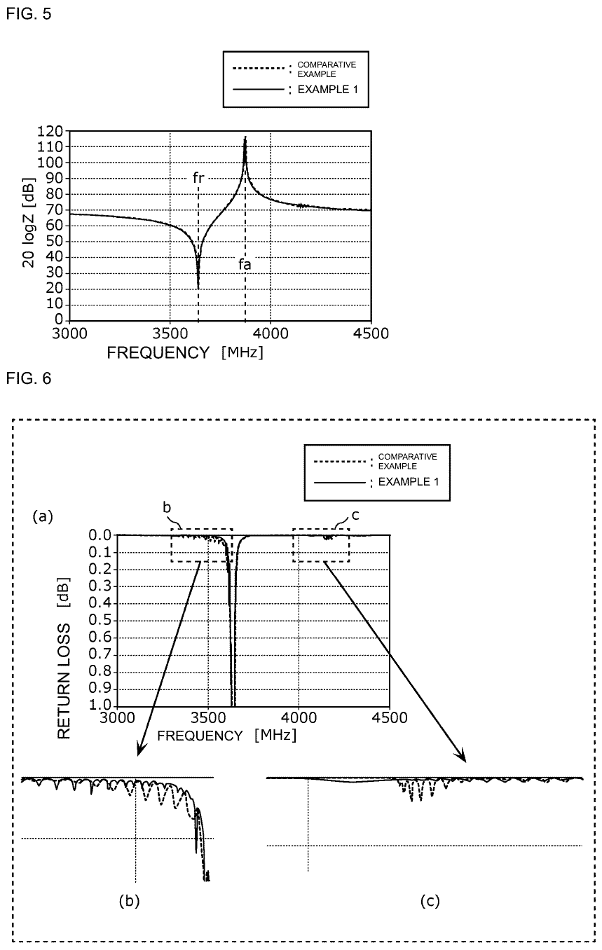

FIG. 5 is a graph indicating impedance characteristics of the acoustic wave elements according to Example 1 and Comparative Example. FIG. 6 is a graph indicating reflection characteristics of the acoustic wave elements according to Example 1 and Comparative Example.

In part (a) of FIG. 6, return loss in the case where a high frequency signal from (a busbar electrode of) one comb-shaped electrode of the acoustic wave element is input to an IDT electrode is illustrated. In this case, the other comb-shaped electrode is short-circuited. In part (b) of FIG. 6, characteristics of a frequency band lower than a resonant frequency fr of the acoustic wave resonator are illustrated in an enlarged manner. In part (c) of FIG. 6, characteristics of a frequency band higher than the resonant frequency fr of the acoustic wave resonator are illustrated in an enlarged manner.

As illustrated in FIG. 5, the impedance characteristics in Example 1 and Comparative Example are substantially the same. In contrast, when attention is paid to the reflection characteristics indicated in part (b) of FIG. 6, at frequencies lower than the resonant frequency fr, the return loss in the acoustic wave element 10 according to Example 1 is smaller than that in the acoustic wave element according to Comparative Example.

More particularly, in Example 1, by setting the value of the IDT-reflector gap G to be smaller than or equal to a value that is about 0.4 times the reflector wave length (λ_{REF}), a spurious wave caused by reflection at the border between the first IDT electrode 11 and the reflector 31 and the border between the second IDT electrode 22 and the reflector 42 is generated near a lower frequency end of a stopband by the reflectors 31 and 42. Herein, a “stopband” is defined as a region in which the wave length of an acoustic wave is made constant by confining the acoustic wave in metal grating of a periodic structure.

In the state in which the spurious wave is generated, by making the reflector wave length (λ_{REF}) greater than the IDT wave length (λ_{IDT}) and shifting the frequency at which the spurious wave is generated towards a lower frequency side, the response characteristics (return loss ripple) of the reflectors 31 and 42 in a region (region b in FIG. 6) lower than the resonant frequency fr of the acoustic wave resonator can be canceled out by the spurious wave.

Thus, the return loss in the region b in the acoustic wave element 10 according to Example 1 can be reduced compared to that in the acoustic wave element according to Comparative Example. Furthermore, in the acoustic wave element 10 according to Example 1, degradation in the return loss in a region (region c in FIG. 6) higher than the anti-resonant frequency fa of the acoustic wave resonator can also be reduced or prevented.

Furthermore, in the acoustic wave element according to Example 1, as indicated in Table 1, the number of pairs of electrode fingers of each of the IDT electrodes 11 and 22 is 80 pairs, which is smaller than the normal number of pairs (for example, 100 pairs). Thus, even in the case where the number of pairs of electrode fingers of each of the IDT electrodes 11 and 22 is small, degradation in the return loss at frequencies lower than the resonant frequency fr of the acoustic wave resonator can be reduced or prevented. Furthermore, since the thickness of the piezoelectric layer 100 is smaller than or equal to the IDT wave length (λ_{IDT}) in Example 1, that is, since the thickness of the piezoelectric layer 100 is smaller than or equal to a value that is twice the array pitch Pi, generation of a higher-order mode can be reduced or prevented.

Reflection Characteristics and Other Characteristics of Acoustic Wave Elements according to Example 2 and Example 3

In each of Example 2 and Example 3, an example in which the IDT-reflector gap is different between the upper side and the lower side of the piezoelectric layer 100 will be described.

The acoustic wave elements 10 according to Example 2 and Example 3 each also include the piezoelectric layer 100, the first IDT electrode 11, the first reflectors 31, the second IDT electrode 22, the second reflectors 42, the protection film 113, the low acoustic velocity layer 153, and the high acoustic velocity support substrate 155.

In the case where the acoustic wave elements 10 according to Example 2 and Example 3 are each seen from a direction perpendicular or substantially perpendicular to a main surface of the piezoelectric layer 100, the first IDT electrode 11 and the second IDT electrode 22 are arranged at the same or substantially the same position and the first reflectors 31 and the second reflectors 42 are arranged at different positions. In other words, in the case where the acoustic wave element 10 is seen from the third direction d3, the first IDT electrode 11 and the second IDT electrode 22 overlap and the first reflectors 31 and the second reflector 42 do not completely overlap and are slightly shifted from each other.

In the acoustic wave elements 10 according to Example 2 and Example 3, materials and thicknesses of the individual layers are the same as or similar to those in Example 1.

Example 2 and Example 3 are different from Example 1 in points described below. Table 2 indicates electrode parameters of the acoustic wave elements according to Example 2 and Example 3.

TABLE 2

| | Example 1 | Example 2 | Example 3 |
|---|---|---|---|
| λ_{R1}/λ_{IDT} | 1.06 | 1.05 | 1.05 |
| Pr1/Pi | 1.06 | 1.05 | 1.05 |
| λ_{R2}/λ_{IDT} | 1.06 | 1.05 | 1.05 |
| Pr2/Pi | 1.06 | 1.05 | 1.05 |
| Number of IDT | 80 | 80 | 80 |
| pairs (pairs) | | | |
| Intersecting | 75.2 | 75.2 | 75.2 |
| width (μm) | | | |
| Number of REF | 10 | 10 | 10 |
| pairs (pairs) | | | |
| G1/λ_{R1} | 0.40 | 0.41 | 0.40 |
| G1/Pr1 | 0.80 | 0.82 | 0.80 |
| G2/λ_{R2} | 0.40 | 0.40 | 0.41 |
| G2/Pr2 | 0.80 | 0.80 | 0.82 |

As indicated in Table 2, in the acoustic wave element according to Example 2, the value of an IDT-reflector gap G1 is about 0.41 times the reflector wave length (λ_{R1}), and the value of an IDT-reflector gap G2 is about 0.40 times the reflector wave length (λ_{R2}). That is, in Example 2, G1 is greater than G2.

Furthermore, in the acoustic wave element according to Example 3, the value of the IDT-reflector gap G1 is 0.40 times the reflector wave length (λ_{R1}), and the value of the IDT-reflector gap G2 is about 0.41 times the reflector wave length (λ_{R2}). That is, in Example 3, G1 is smaller than G2.

Furthermore, in the acoustic wave elements according to Example 2 and Example 3, the reflector wave length (λ_{R1}) is about 1.05 times the IDT wave length (λ_{IDT}), and the reflector wave length (λ_{R2}) is about 1.05 times the IDT wave length (λ_{IDT}). That is, in Example 2 and Example 3, λ_{R1} is equal or substantially equal to λ_{R2}.

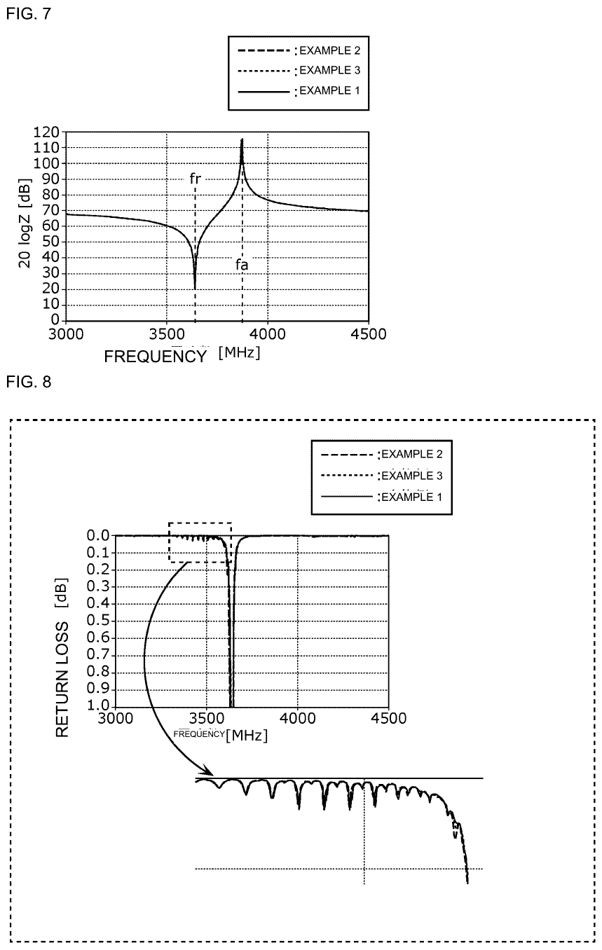

FIG. 7 is a graph indicating impedance characteristics of the acoustic wave elements according to Example 1, Example 2, and Example 3. FIG. 8 is a graph indicating reflection characteristics of the acoustic wave elements according to Example 1, Example 2, and Example 3.

As illustrated in FIG. 7, the impedance characteristics in Example 1, Example 2, and Example 3 are the same or substantially the same. Furthermore, as illustrated in FIG. 8, the reflection characteristics in Example 1, Example 2, and Example 3 are the same or substantially the same. Specifically, even if G1/λ_{R1} is greater than G2/λ_{R2} by about 0.01 as in Example 2, the reflection characteristics in Example 2 are substantially the same or substantially the same as the reflection characteristics in Example 1. Even if G2/λ_{R2} is greater than G1/λ_{R1} by about 0.01 as in Example 3, the reflection characteristics in Example 3 are the same or substantially the same as the reflection characteristics in Example 1. As described above, even in the case where the IDT-reflector gap G1 and the IDT-reflector gap G2, which are on the upper side and the lower side of the piezoelectric layer 100, respectively, are different, return loss at a frequency lower than the resonant frequency fr can be reduced. Thus, the flexibility of design can be increased.

In the acoustic wave elements 10 according to Example 2 and Example 3, the thickness of the piezoelectric layer 100 is smaller than or equal to the IDT wave length (λ_{IDT}), the value of the IDT-reflector gap G1 is smaller than a value that is about 0.5 times the reflector wave length (λ_{R1}), the value of the IDT-reflector gap G2 is smaller than a value that is about 0.5 times the reflector wave length (λ_{R1}), and each of the reflector wave length (λ_{R1}) and the reflector wave length (λ_{R2}) is greater than the IDT wave length (λ_{IDT}).

In other words, in the acoustic wave elements 10 according to Example 2 and Example 3, the thickness of the piezoelectric layer 100 is smaller than or equal to a value that is twice the array pitch Pi, the IDT-reflector gap G1 is smaller than the array pitch Pr1 (G1<Pr1), the IDT-reflector gap G2 is smaller than the array pitch Pr2 (G2<Pr2), and each of the array pitches Pr1 and Pr2 is greater than the array pitch Pi (Pr1>Pi, Pr2>Pi).

As with the acoustic wave element according to Example 1, return loss at a frequency lower than the resonant frequency fr can be reduced in the acoustic wave elements 10 according to Example 2 and Example 3.

Reflection Characteristics and Other Characteristics of Acoustic Wave Elements according to Example 4 and Example 5

In each of Example 4 and Example 5, an example in which the reflector wave length is different between the upper side and the lower side of the piezoelectric layer 100 will be described.

The acoustic wave elements 10 according to Example 4 and Example 5 each also include the piezoelectric layer 100, the first IDT electrode 11, the first reflectors 31, the second IDT electrode 22, the second reflectors 42, the protection film 113, the low acoustic velocity layer 153, and the high acoustic velocity support substrate 155.

In the case where the acoustic wave elements 10 according to Example 4 and Example 5 are each seen from a direction perpendicular or substantially perpendicular to a main surface of the piezoelectric layer 100, the first IDT electrode 11 and the second IDT electrode 22 are arranged at the same or substantially the same position, the first reflectors 31 and the second reflectors 42 have the same IDT-reflector gap, and the first reflectors 31 and the second reflectors 42 have different array pitches of reflection electrode fingers. In other words, in the case where the piezoelectric layer 100 is seen from the third direction d3, the first IDT electrode 11 and the second IDT electrode 22 overlap and the array pitches of reflection electrode fingers of the first reflectors 31 and the second reflectors 42 are slightly shifted from each other.

In the acoustic wave elements 10 according to Example 4 and Example 5, materials and thicknesses of the individual layers are the same as or similar to those in Example 1.

Example 4 and Example 5 are different from Example 1 in points described below. Table 3 indicates electrode parameters of the acoustic wave elements according to Example 4 and Example 5.

TABLE 3

| | Example 1 | Example 4 | Example 5 |
|---|---|---|---|
| λ_{R1}/λ_{IDT} | 1.06 | 1.05 | 1.05 |
| Pr1/Pi | 1.06 | 1.05 | 1.05 |
| λ_{R2}/λ_{IDT} | 1.06 | 1.045 | 1.060 |
| Pr2/Pi | 1.06 | 1.045 | 1.060 |
| Number of IDT | 80 | 80 | 80 |
| pairs (pairs) | | | |
| Intersecting | 75.2 | 75.2 | 75.2 |
| width (μm) | | | |
| Number of REF | 10 | 10 | 10 |
| pairs (pairs) | | | |
| G1/λ_{R1} | 0.40 | 0.40 | 0.40 |
| G1/Pr1 | 0.80 | 0.80 | 0.80 |
| G2/λ_{R2} | 0.40 | 0.40 | 0.40 |
| G2/Pr2 | 0.80 | 0.80 | 0.80 |

As indicated in Table 3, in the acoustic wave elements according to Example 4 and Example 5, the value of the IDT-reflector gap G1 is about 0.40 times the reflector wave length (λ_{R1}), and the value of the IDT-reflector gap G2 is about 0.40 times the reflector wave length (λ_{R2}). That is, in Example 4 and Example 5, G1 is equal or substantially equal to G2. Furthermore, in the acoustic wave element according to Example 4, the reflector wave length (λ_{R1}) is about 1.05 times the IDT wave length (λ_{IDT}), and the reflector wave length (λ_{R2}) is about 1.045 times the IDT wave length (λ_{IDT}). That is, in Example 4, λ_{R1} is greater than λ_{R2}.

Furthermore, in the acoustic wave element according to Example 5, the reflector wave length (λ_{R1}) is about 1.05 times the IDT wave length (λ_{IDT}), and the reflector wave length (λ_{R2}) is about 1.060 times the IDT wave length (λ_{IDT}). That is, in Example 5, λ_{R1} is smaller than λ_{R2}.

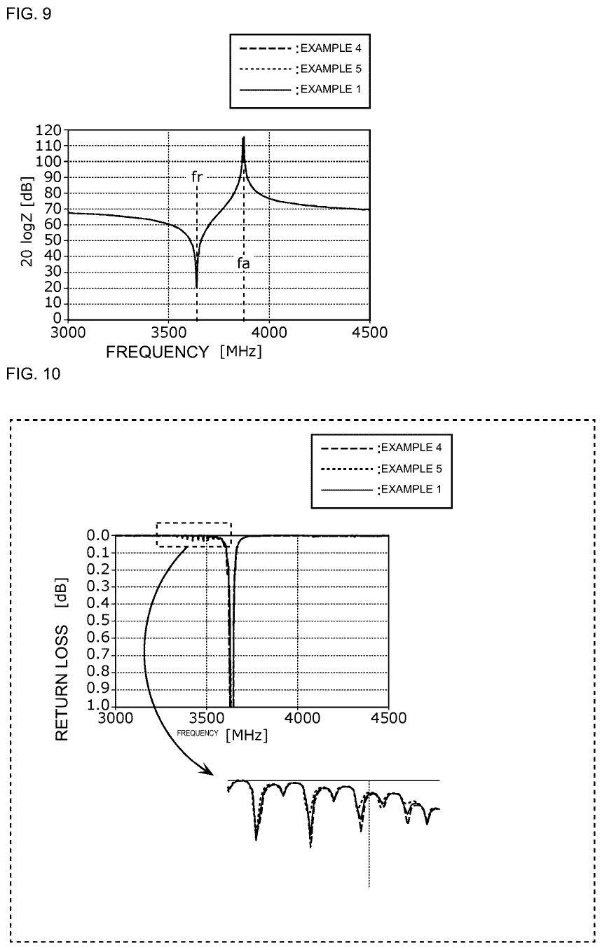

FIG. 9 is a graph indicating impedance characteristics of the acoustic wave elements according to Example 1, Example 4, and Example 5. FIG. 10 is a graph indicating reflection characteristics of the acoustic wave elements according to Example 1, Example 4, and Example 5.

As illustrated in FIG. 9, the impedance characteristics in Example 1, Example 4, and Example 5 are the same or substantially the same. Furthermore, as illustrated in FIG. 10, the reflection characteristics in Example 1, Example 4, and Example 5 are the same or substantially the same. Specifically, even if λ_{R2}/λ_{IDT} is smaller than λ_{R1}/λ_{IDT} by about 0.005 as in Example 4, the reflection characteristics in Example 4 are the same or substantially the same as the reflection characteristics in Example 1. Even if λ_{R2}/λ_{IDT} is greater than λ_{R1}/λ_{IDT} by about 0.01 as in Example 5, the reflection characteristics in Example 5 are the same or substantially the same as the reflection characteristics in Example 1. As described above, even in the case where the reflector wave length Ari and the reflector wave length λR, which are on the upper side and the lower side of the piezoelectric layer 100, respectively, are different, return loss at a frequency lower than the resonant frequency fr can be reduced. Thus, flexibility of design can be increased.

In the acoustic wave elements 10 according to Example 4 and Example 5, the thickness of the piezoelectric layer 100 is smaller than or equal to the IDT wave length (λ_{IDT}), the value of the IDT-reflector gap G1 is smaller than a value that is about 0.5 times the reflector wave length (λ_{R1}), the value of the IDT-reflector gap G2 is smaller than a value that is about 0.5 times the reflector wave length (λ_{R2}), and each of the reflector wave length (λ_{R1}) and the reflector wave length (λ_{R2}) is greater than the IDT wave length (λ_{IDT}).

In other words, the thickness of the piezoelectric layer 100 is smaller than or equal to a value that is twice the array pitch Pi, the IDT-reflector gap G1 is smaller than the array pitch Pr1 (G1<Pr1), the IDT-reflector gap G2 is smaller than the array pitch Pr2 (G2<Pr2), and each of the array pitches Pr1 and Pr2 is greater than the array pitch Pi (Pr1>Pi, Pr2>Pi).

As with the acoustic wave element according to Example 1, return loss at a frequency lower than the resonant frequency fr can be reduced in the acoustic wave elements 10 according to Example 4 and Example 5.

Reflection Characteristics of Acoustic Wave Elements according to Examples 1b to 1h, 2a to 2h, 3a to 3h, and 4a to 4h

Steps for constructing the acoustic wave element 10 according to the present example embodiment will be described below.

First, the IDT-reflector gap G is preferably set to be smaller than each of the gap between a plurality of electrode fingers of an IDT electrode and the gap between reflector electrode fingers of a reflector, that is, for example, smaller than a value that is about 0.5 times the reflector wave length (λ_{REF}) (Step 1).

Thus, a spurious wave caused by reflection at the border between the IDT electrode and the reflector is generated near a lower frequency end of the stopband by the reflector.

Next, the reflector wave length (λ_{REF}) is set to be greater than the IDT wave length (λ_{IDT}) (Step 2).

Thus, the generation frequency of the spurious wave generated in Step 1 is shifted towards a lower frequency side. As a result, response characteristics (return loss ripple) as the reflector for the IDT electrode in a frequency region lower than the resonant frequency fr of the acoustic wave resonator configuring the acoustic wave element 10 are canceled out by the spurious wave.

By Step 1 and Step 2, in the acoustic wave element 10 according to the present example embodiment, the return loss (return loss ripple) in the frequency region lower than the resonant frequency fr can be reduced. Furthermore, by reducing the number of pairs of the electrode fingers of the IDT electrode, an increase of the return loss at a frequency lower than the resonant frequency fr of the acoustic wave resonator can be reduced or prevented.

Regarding 1 and Step 2, the reflection characteristics of the acoustic wave elements according to Examples 1b to 1h, Examples 2a to 2h, Examples 3a to 3h, and Examples 4a to 4h will be described below.

First, conditions of generation of a spurious wave, which is caused to be generated by reflection between the IDT electrode and the reflector (Step 1) in order to cancel out the response characteristics (hereinafter, referred to as reflection response) as the reflector for the IDT electrode in the frequency region lower than the resonant frequency fr of the acoustic wave element, will be described.

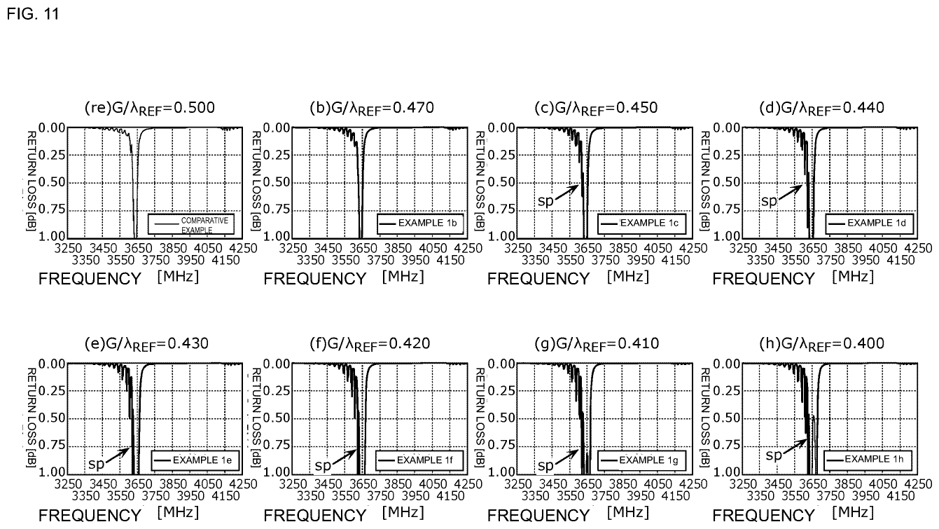

FIG. 11 includes graphs indicating reflection characteristics of an acoustic wave element in the case where IDT-reflector gap/reflector wave length is changed.

Part (re) of FIG. 11 is a graph indicating, for a monitoring purpose, reflection characteristics of the acoustic wave element according to Comparative Example. In part (re) of FIG. 11, the reflection characteristics in the case where IDT-reflector gap G/reflector wave length (λ_{REF}) is about 0.500 are illustrated.

Parts (b) to (h) of FIG. 11 are graphs indicating the reflection characteristics of the acoustic wave elements according to Examples 1b to 1h. In parts (b) to (h) of FIG. 11, the return loss in the case where IDT-reflector gap G/reflector wave length (λ_{REF}) is from about 0.470 to about 0.400 is illustrated. In parts (b) to (h) of FIG. 11, examples in which the IDT-reflector gap G is changed while the reflector wave length (λ_{REF}) being fixed at 1 are illustrated.

As illustrated in parts (c) to (h) of FIG. 11, by setting IDT-reflector gap G/reflector wave length (λ_{REF}) to be smaller than about 0.450, a spurious wave (a local minimum indicated by an arrow in each of parts (c) to (h) of FIG. 11: hereinafter, referred to as a spurious wave sp) caused by reflection between the IDT electrode and the reflector is generated. Furthermore, the return loss of the spurious wave sp increases as G/λ_{REF} decreases.

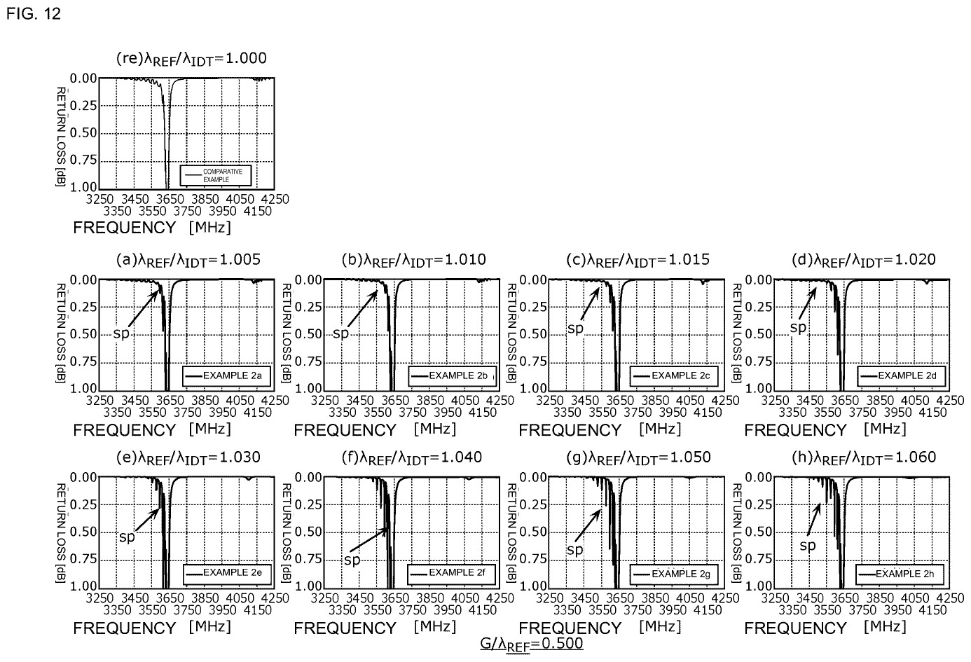

FIG. 12 includes graphs indicating reflection characteristics of an acoustic wave element in the case where reflector wave length/IDT wave length is changed. In FIG. 12, cases where IDT-reflector gap G/reflector wave length (λ_{REF}) is about 0.500 are illustrated.

Part (re) of FIG. 12 is a graph indicating, for a monitoring purpose, reflection characteristics of the acoustic wave element according to Comparative Example. In part (re) of FIG. 12, the reflection characteristics in the case where reflector wave length (λ_{REF})/IDT wave length (λ_{IDT}) is 1.000 are illustrated.

Parts (a) to (h) of FIG. 12 are graphs indicating reflection characteristics of the acoustic wave elements according to Examples 2a to 2h. As illustrated in parts (a) to (h) of FIG. 12, although sharpness at a stopband end of the reflector is improved only by changing the reflector wave length, the improvement range is very small. Furthermore, since frequencies higher than a reduced portion are included within the stopband, the spurious wave caused by reflection of the IDT increases.

As illustrated in FIG. 12, when IDT-reflector gap G/reflector wave length (λ_{REF}) is about 0.500, a spurious wave cannot be improved. Thus, IDT-reflector gap G/reflector wave length (λ_{REF}) needs to be smaller than about 0.500. In other words, G/Pr needs to be smaller than about 1.

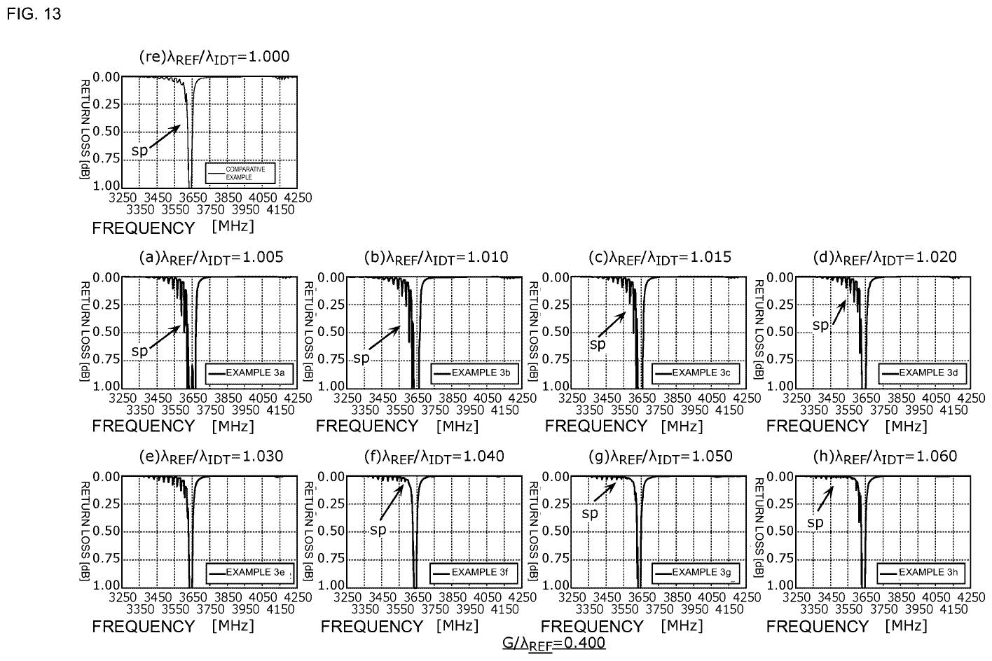

FIG. 13 includes graphs indicating reflection characteristics of an acoustic wave element in the case where reflector wave length/IDT wave length is changed. In FIG. 13, cases where IDT-reflector gap G/reflector wave length (λ_{REF}) is about 0.400 are illustrated.

Part (re) of FIG. 13 is a graph indicating, for a monitoring purpose, reflection characteristics of the acoustic wave element according to Comparative Example. In part (re) of FIG. 13, the reflection characteristics in the case where reflector wave length (λ_{REF})/IDT wave length (λ_{IDT}) is about 1.000 are illustrated.

Parts (a) to (h) of FIG. 13 are graphs indicating reflection characteristics of the acoustic wave elements according to Examples 3a to 3h. As illustrated in parts (a) to (d) of FIG. 13, by setting a large reflector wave length, the position at which the spurious wave sp is generated can be moved towards a lower frequency side. As illustrated in parts (f) to (h) of FIG. 13, when the position at which the spurious wave sp is generated is moved to a frequency side lower than the resonant point, return loss can be improved.

As illustrated in FIG. 13, by setting the reflector wave length (λ_{REF}) to be greater than the IDT wave length (λ_{IDT}) under the condition that IDT-reflector gap G/reflector wave length (λ_{REF}) is about 0.400, the position at which the spurious wave sp is generated can be moved towards a lower frequency side, and the return loss can be improved. In other words, by setting Pr to be greater than Pi under the condition that G/Pr is about 0.800, the position at which the spurious wave sp is generated can be moved towards a lower frequency side, and the return loss can be improved.

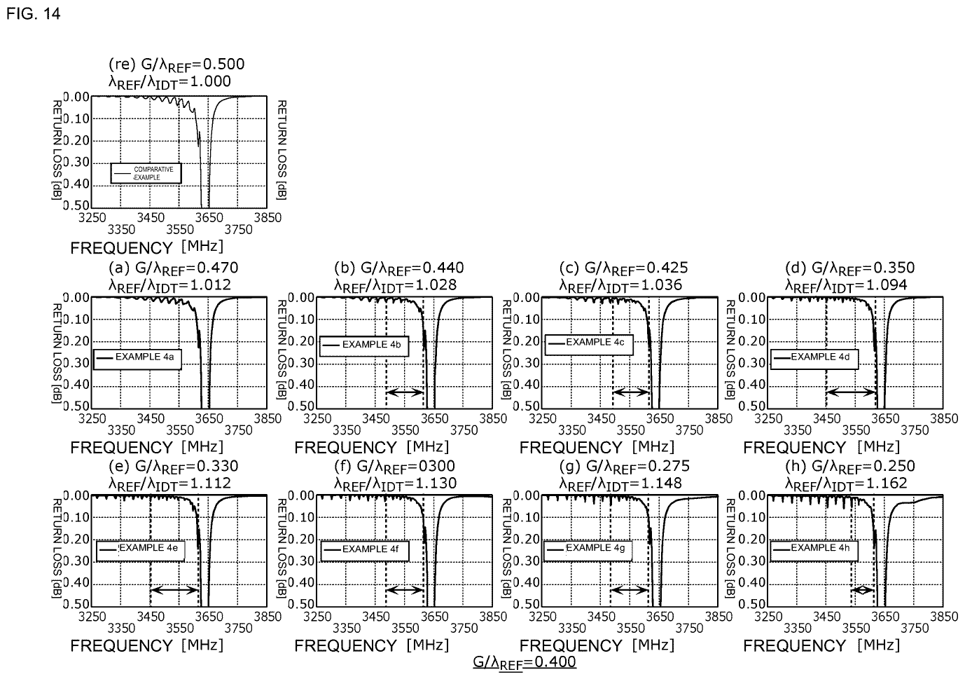

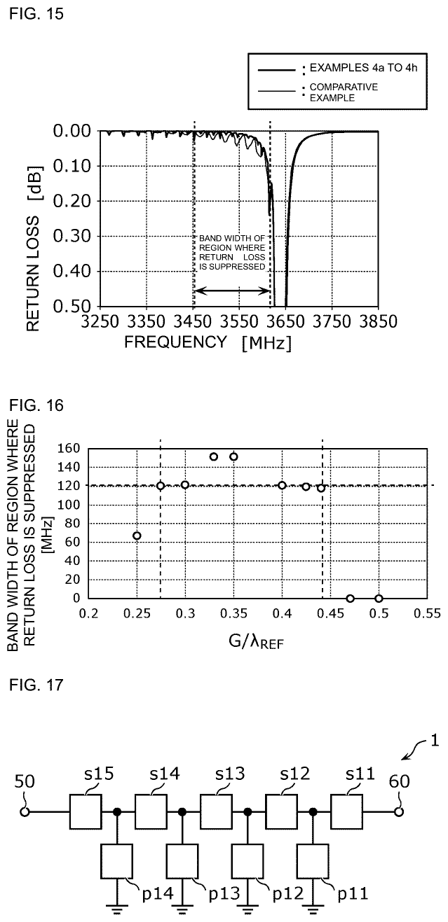

FIG. 14 includes graphs indicating reflection characteristics of an acoustic wave element in the case where IDT-reflector gap/reflector wave length and reflector wave length/IDT wave length are changed. FIG. 15 is a diagram illustrating the band width of a region where return loss is reduced.

Part (re) of FIG. 14 is a graph indicating, for a monitoring purpose, reflection characteristics of the acoustic wave element according to Comparative Example. In part (re) of FIG. 14, the reflection characteristics in the case where IDT-reflector gap G/reflector wave length (λ_{REF}) is about 0.500 and reflector wave length (λ_{REF})/IDT wave length (λ_{IDT}) is about 1.000 are illustrated.

Parts (a) to (h) of FIG. 14 are graphs indicating the reflection characteristics of the acoustic wave elements according to Examples 4a to 4h. In each of parts (a) to (h) of FIG. 14, a band width in which ripple level from a lower frequency side to a higher frequency side is substantially the same as that in Comparative Example, as illustrated in FIG. 15, is illustrated as a band width of the region where the return loss is reduced.

In the case of part (a) of FIG. 14, although the amount of spurious wave generation is slightly improved, the spurious wave does not completely disappear. As proceeding from parts (b) to (d) of FIG. 14, the range where the spurious wave sp is reduced or prevented increases. Furthermore, as proceeding from parts (e) to (h) of FIG. 14, the range where the spurious wave sp is reduced or prevented decreases. The results obtained from FIGS. 13 and 14 are summarized and illustrated in FIG. 16.

FIG. 16 is a graph indicating the relationship between IDT-reflector gap/reflector wave length and the band width of a region where return loss is reduced.

In FIG. 16, the horizontal axis represents IDT-reflector gap G/reflector wave length (λ_{REF}), and the vertical axis represents the band width of a region where return loss is reduced. In the present example, a state in which the band width of the region where the return loss is reduced is equal to or more than about 120 MHz, is evaluated as a sufficient improvement of the return loss.

As illustrated in FIG. 16, when IDT-reflector gap/reflector wave length is equal to or greater than about 0.275 and smaller than or equal to about 0.44, the band width of the region where the return loss is reduced is equal to or more than about 120 MHz. In other words, when (IDT-reflector gap G/array pitch Pr of reflection electrode fingers) is equal to or greater than about 0.55 and smaller than or equal to about 0.88, the band width of the region where the return loss is reduced is equal to or more than about 120 MHz. Thus, by setting G/Pr to be equal to or greater than about 0.55 and smaller than or equal to about 0.88, the band width of the region where the return loss is reduced can be increased.

### Second Example Embodiment

In a second example embodiment of the present invention, an acoustic wave filter device of a ladder type including the acoustic wave element 10 according to the first example embodiment will be described.

FIG. 17 is a diagram illustrating a circuit configuration of an acoustic wave filter device 1 according to the second example embodiment. As illustrated in FIG. 17, the acoustic wave filter device 1 preferably includes series-arm resonators s11, s12, s13, s14, and s15, parallel-arm resonators p11, p12, p13, and p14, and terminals 50 and 60.

The series-arm resonators s11 to s15 are connected in series between the terminals 50 and 60. Furthermore, the parallel-arm resonators p11 to p14 are connected in parallel between connection points of the terminal 50, the series-arm resonators s11 to s15, and the terminal 60 and a reference terminal (ground). With the connection configuration of the series-arm resonators s11 to s15 and the parallel-arm resonators p11 to p14 described above, the acoustic wave filter device 1 includes a ladder-type band pass filter. A circuit element such as, for example, an inductor may be inserted between the parallel-arm resonators p11 to p14 and the ground.

In the second example embodiment, all of the series-arm resonators s11 to s15 and the parallel-arm resonators p11 to p14 among the resonators included in the acoustic wave filter device 1 may be the acoustic wave element 10 described above. Furthermore, only the parallel-arm resonators p11 to p14 among the resonators included in the acoustic wave filter device 1 may be the acoustic wave element 10 described above. Furthermore, the parallel-arm resonator p14 or the series-arm resonator s15 that is closest to the terminal 50, which is connected to a common terminal, among the resonators included in the acoustic wave filter device 1 may be the acoustic wave element 10 described above.

The acoustic wave filter device 1 may include the configuration of the acoustic wave element according to the first example embodiment. The circuit configuration illustrated in FIG. 17 is merely an example. The number of series-arm resonators, the number of parallel-arm resonators, a connection point of an inductor, and the like are not limited to the arrangement illustrated in FIG. 17. Furthermore, although the ladder-type circuit configuration is illustrated as an example in FIG. 17, a longitudinally-coupled-type resonant circuit may be included.

### Third Example Embodiment

In a third example embodiment of the present invention, a multiplexer in which a plurality of filters including the acoustic wave filter device 1 according to the second example embodiment are connected directly or indirectly to a common terminal will be described.

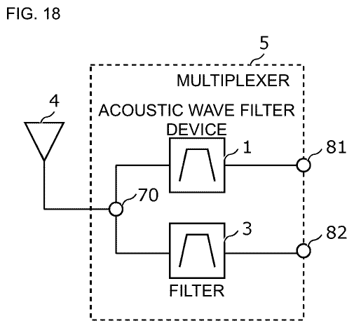

FIG. 18 is a circuit configuration diagram of a multiplexer 5 according to the third example embodiment and a peripheral circuit (antenna 4) for the multiplexer 5. The multiplexer 5 illustrated in FIG. 18 includes the acoustic wave filter device 1, a filter 3, a common terminal 70, and input/output terminals 81 and 82.

In the acoustic wave filter device 1, the terminal 50 of the acoustic wave filter device 1 is connected to the common terminal 70, and the terminal 60 of the acoustic wave filter device 1 is connected to the input/output terminal 81.

The filter 3 is connected to the common terminal 70 and the input/output terminal 82. The filter 3 is, for example, a ladder-type acoustic wave filter including parallel-arm resonators and series-arm resonators. However, the filter 3 may be an LC filter or other types of filter, and the circuit configuration of the filter 3 is not particularly limited.

The pass band of the acoustic wave filter device 1 is higher than the pass band of the filter 3.

The acoustic wave filter device 1 and the filter 3 are not necessarily directly connected to the common terminal 70, unlike in FIG. 18. For example, the acoustic wave filter device 1 and the filter 3 may be indirectly connected to the common terminal 70 with an impedance matching circuit, a phase shifter, a circulator, or a switch element capable of selecting two or more filters interposed therebetween.

In the present example embodiment, a circuit configuration in which two filters, as the multiplexer 5, are connected to the common terminal 70 is provided. However, the number of filters connected to the common terminal 70 is not necessarily two. Three or more filters may be connected to the common terminal 70. That is, a multiplexer according to the present invention may include a plurality of filters including the acoustic wave filter device 1. One of input/output terminals of the plurality of filters may be connected directly or indirectly to the common terminal, and at least one of the plurality of filters except the acoustic wave filter device 1 may have a pass band whose frequencies are lower than frequencies of a pass band of the acoustic wave filter device 1.

### SUMMARY

Configurations of an acoustic wave element and other elements according to aspects of the present invention will be exemplified below.

### Aspect 1

The acoustic wave element 10 according to an aspect of the present invention includes IDT electrodes that are provided on two main surfaces of the piezoelectric layer 100, and a plurality of reflectors that are provided on both the main surfaces. The IDT electrodes each include a pair of comb-shaped electrodes that are opposite to each other. Each of the comb-shaped electrodes defining the pair of comb-shaped electrodes includes a plurality of electrode fingers that are arranged to extend in the second direction d2 that intersects the first direction d1 in a direction along a main surface of the piezoelectric layer 100, and a busbar electrode that connects one ends of the plurality of electrode fingers. The plurality of reflectors are arranged on two outer sides of the IDT electrode in the first direction d1 and each include a plurality of reflection electrode fingers that are arranged to extend in the second direction d2. In a case where an array pitch of the plurality of electrode fingers arranged along the first direction d1 is represented by Pi, an array pitch of the plurality of reflection electrode fingers arranged along the first direction d1 is represented by Pr, and an IDT-reflector gap that is a distance in the first direction d1 between a center of an electrode finger that is closest to the reflector among the plurality of electrode fingers and a center of a reflection electrode finger that is closest to the IDT electrode among the plurality of reflection electrode fingers is represented by G, a thickness of the piezoelectric layer 100 is smaller than or equal to a value that is twice Pi, G is smaller than Pr, and Pr is greater than Pi.

In an acoustic wave resonator located at a substrate including the piezoelectric layer 100, return loss may be increased due to response characteristics as a reflector for an IDT electrode at a frequency lower than the resonant frequency fr of the acoustic wave resonator. In particular, as the number of pairs of electrode fingers defining an IDT electrode is reduced so that a reduction in size is achieved, the return loss tends to increase.

In contrast, with the configuration described above, by setting the IDT-reflector gap G to be smaller than the array pitch Pr of the reflection electrode fingers, a spurious wave caused by reflection at the border between the IDT electrode and the reflector is generated near a lower frequency end of the stopband of the reflector. By, in the state in which the spurious wave is generated, setting the array pitch Pr of the reflection electrode fingers to be greater than the array pitch Pi of the electrode fingers and shifting the frequency at which the spurious wave is generated towards a lower frequency side, response characteristics as the reflector for the IDT electrode at a frequency lower than the resonant frequency fr of the acoustic wave resonator can be canceled out by the spurious wave. Thus, an increase of the return loss at a frequency lower than the resonant frequency fr of the acoustic wave resonator can be reduced or prevented.

Furthermore, by shifting the position of a higher frequency end of the stopband, a generation frequency of a reflection response that reflects a generation frequency of the stopband and a reflector wave length can be changed. Thus, the reflection response at the higher frequency end of the stopband (at a frequency higher than the anti-resonant frequency fa of the acoustic wave resonator) can be dispersed.

### Aspect 2

G/Pr is equal to or greater than about 0.55 and smaller than or equal to about 0.88.

Accordingly, the band width of a region where return loss is reduced can be increased. The configuration of Aspect 2 can be applied to Aspect 1.

### Aspect 3

The piezoelectric layer 100 includes the first main surface 100a that is one of the main surfaces and the second main surface 100b that is the other one of the main surfaces. The IDT electrodes provided on both of the main surfaces of the piezoelectric layer 100 include the first IDT electrode 11 that is provided on the first main surface 100a and the second IDT electrode 22 that is provided on the second main surface 100b. The plurality of reflectors include the plurality of first reflectors 31 that are arranged on both the outer sides of the first IDT electrode 11 in the first direction d1 and the plurality of second reflectors 42 that are arranged on both the outer sides of the second IDT electrode 22 in the first direction d1. The comb-shaped electrode 11A included in the first IDT electrode 11 and the comb-shaped electrode 22A included in the second IDT electrode 22 are electrically connected. The comb-shaped electrode 11B included in the first IDT electrode 11 and the comb-shaped electrode 22B included in the second IDT electrode 22 are electrically connected.

As described above, by connecting one comb-shaped electrode and connecting other comb-shaped electrode, interaction between the first IDT electrode 11 and the second IDT electrode 22 can be achieved. Thus, generation of a higher-order mode in the acoustic wave element 10 can be reduced or prevented or minimized. The configuration of Aspect 3 can be applied to Aspect 1 or Aspect 2.

### Aspect 4

The acoustic wave element 10 further includes the high acoustic velocity support substrate 155 in which bulk waves propagate at an acoustic velocity higher than an acoustic velocity of acoustic waves propagating in the piezoelectric layer 100, and the low acoustic velocity layer 153 in which bulk waves propagate at an acoustic velocity lower than an acoustic velocity of acoustic waves propagating in the piezoelectric layer 100, the low acoustic velocity layer 153 being disposed between the high acoustic velocity support substrate 155 and the piezoelectric layer 100. The low acoustic velocity layer 153 is provided on the second main surface 100b in such a manner that the low acoustic velocity layer 153 covers the second IDT electrode 22.

As described above, since the second IDT electrode 22 is embedded in the low acoustic velocity layer 153, a part of the piezoelectric layer 100 where acoustic waves are excited is also supported by the low acoustic velocity layer 153. Thus, the shape of the piezoelectric layer 100 is less likely to be changed, and fluctuations in electrical characteristics can be reduced or prevented. Furthermore, since the second IDT electrode 22 is embedded in the low acoustic velocity layer 153, a higher-order mode can be made to leak to the low acoustic velocity layer 153 side. Thus, generation of a higher-order mode can be reduced or prevented.

Furthermore, in the case where an IDT electrode of the acoustic wave element 10 is formed at a substrate having a multilayer structure including the piezoelectric layer 100, the low acoustic velocity layer 153, and the high acoustic velocity support substrate 155, a Q value of the acoustic wave element 10 is high. Thus, the reflection response is high. In contrast, by setting the array pitch Pr to be greater than the array pitch Pi and setting the IDT-reflector gap G to be smaller than the array pitch Pr, a large effect of reducing or preventing reflection response at a lower frequency end or a higher frequency end of the stopband can be achieved. The configuration of Aspect 4 can be applied to Aspect 3.

### Aspect 5

The acoustic wave element 10 further includes the protection film 113 that is provided on the first main surface 100a in such a manner that the protection film 113 covers the first IDT electrode 11.

As described above, since the acoustic wave element 10 includes the protection film 113, the electrode layer 110a can be protected from external environment. Furthermore, frequency-temperature characteristics can be adjusted or moisture resistance can be increased. The configuration of Aspect 5 can be applied to Aspect 3 or Aspect 4.

### Aspect 6

The acoustic wave filter device 1 according to an aspect of the present invention includes the acoustic wave element 10 described above.

By configuring the acoustic wave filter device 1 to include the acoustic wave element 10 described above, degradation of insertion loss inside the pass band caused by response characteristics of the reflector can be reduced or prevented. The configuration of Aspect 6 can be applied to any one of Aspects 1 to 5.

### Aspect 7

The multiplexer 5 according to an aspect of the present invention includes a plurality of filters 3 including the acoustic wave filter device 1 described above. One of the input/output terminal 81 and the input/output terminal 82 of the plurality of filters 3 is connected directly or indirectly to the common terminal 70, and at least one of the plurality of filters 3 except the acoustic wave filter device 1 has a pass band whose frequencies are lower than frequencies of a pass band of the acoustic wave filter device 1.

Thus, in the acoustic wave filter device 1, an attenuation in an attenuation band lower than the pass band can be increased. Thus, insertion loss inside the pass band of the filter that is lower than the pass band of the acoustic wave filter device 1 can be reduced.

### OTHER EXAMPLE EMBODIMENTS

An acoustic wave element, an acoustic wave filter device, and a multiplexer according to example embodiments of the present invention have been described above as example embodiments and examples. However, acoustic wave elements, acoustic wave filter devices, and multiplexers according to the present invention are not limited to the example embodiments and examples described above. Other example embodiments provided by combining component elements in example embodiments and examples described above, examples obtained by making various modifications to example embodiments described above that are conceived by those skilled in the art without departing from the spirit of the present invention, various types of equipment including an acoustic wave element, an acoustic wave filter device, and a multiplexer disclosed herein are also included in the present invention.

For example, an acoustic wave filter device 1 according to an example embodiment of the present invention may further include circuit elements, such as an inductor and a capacitor.

Furthermore, an acoustic wave element according to the present invention is not necessarily a surface acoustic wave resonator in the first example embodiment and may be an acoustic wave resonator using acoustic boundary waves.

Although an example in which the low acoustic velocity layer 153 and the high acoustic velocity support substrate 155 are provided on the second main surface 100b side of the piezoelectric layer 100 has been described above, the low acoustic velocity layer 153 and the high acoustic velocity support substrate 155 are not necessarily provided on the second main surface 100b side. Only a support substrate may be provided on the second main surface 100b side of the piezoelectric layer 100.

Furthermore, the acoustic wave element 10 illustrated in FIGS. 1A, 1B, 2, and 3 explains a typical structure thereof. The number of electrode fingers that define an electrode, the length of each of the electrode fingers, and the like are not limited to the structure described above. Furthermore, materials of individual layers such as the piezoelectric layer 100 illustrated in the multiplayer structure described above are merely examples. For example, a material may be changed according to important characteristics among required high frequency propagation characteristics.

In an example embodiment described above, the array pitch Pi of electrode fingers represents, for example, the distance in the first direction d1 between the center of the electrode finger 11a and the center of the electrode finger 11b, the electrode fingers 11a and 11b being included in the first IDT electrode 11 and being adjacent to each other in the first direction d1. All of the array pitches of the plurality of electrode fingers 11a and 11b in the IDT electrode 11 may be the same or substantially the same or a portion of or all of the array pitches may be different.

The array pitch Pi of electrode fingers may be derived as described below. For example, the total number of electrode fingers 11a and 11b included in the IDT electrode 11 is represented by Ni. The distance between the center of an electrode finger at one end of the IDT electrode 11 in the first direction d1 and the center of an electrode finger at the other end of the IDT electrode 11 in the first direction d1 is represented by Di. In this case, the array pitch Pi of the electrode fingers can be expressed by an equation Pi=Di/(Ni−1). (Ni−1) can also be expressed as the total number of gaps formed by electrode fingers that are adjacent to each other in the IDT electrode 11. The same applies to the IDT electrode 22.

The array pitch Pr of reflection electrode fingers represents, for example, the distance between the centers in the first direction d1 of reflection electrode fingers 31a that are adjacent to each other in the first direction d1 among the plurality of reflection electrode fingers 31a included in the reflector 31. All of the array pitches of the plurality of reflection electrode fingers 31a in the reflector 31 may be the same or substantially the same or a portion of or all of the array pitches may be different.

The array pitch Pr of reflection electrode fingers can be derived as described below. For example, the total number of the reflection electrode fingers 31a included in the reflector 31 is represented by Nr. The distance between the center of a reflection electrode finger at one end of the reflector 31 in the first direction d1 and the center of a reflection electrode finger at the other end of the reflector 31 in the first direction d1 is represented by Dr. In this case, the array pitch Pr of the reflection electrode fingers can be expressed by an equation Pr=Dr/(Nr−1). (Nr−1) can also be expressed as the total number of gaps formed by reflection electrode fingers that are adjacent to each other in the reflector 31. The same applies to the reflector 42.

Regarding a measurement position for the pitch of electrode fingers, the pitch is obtained from a distance between the center points or substantially the center points in the first direction d1 of the widths of predetermined electrode fingers that are adjacent to each other. Alternatively, the pitch may be obtained from the average of distances corresponding to two points that substantially equally divide the intersecting widths of individual electrode fingers into three in the second direction or distances corresponding to three points that substantially equally divide the intersecting widths of individual electrode fingers into four in the second direction. Regarding a method for measuring the pitch of electrode fingers, a cross section passing through an imaginary line parallel or substantially parallel to the first direction d1 may be obtained by, for example, an optical microscope, SEM observation, polishing, or the like from the top surface (direction perpendicular or substantially perpendicular to both the first direction d1 and the second direction d2) and measurement can be made based on length measurement by the optimal microscope or SEM observation.

Example embodiments of the present invention may be widely usable, for example, as low-loss and compact acoustic wave element, acoustic wave filter, and multiplexer applicable to multi-band and multi-mode frequency standards, for communication equipment such as mobile phones.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave element comprising:
a piezoelectric layer;
interdigital transducer (IDT) electrodes on two main surfaces of the piezoelectric layer; and
a plurality of reflectors on both of the two main surfaces; wherein
the IDT electrodes each include a pair of comb-shaped electrodes that are opposite to each other;
each of the comb-shaped electrodes defining the pair of comb-shaped electrodes includes a plurality of electrode fingers extending in a second direction that intersects a first direction in a direction along a main surface of the piezoelectric layer, and a busbar electrode connecting single ends of the plurality of electrode fingers;
the plurality of reflectors are arranged on two outer sides of the IDT electrode in the first direction and each include a plurality of reflection electrode fingers extending in the second direction; and
in a case where:
an array pitch of the plurality of electrode fingers arranged along the first direction is represented by Pi;
an array pitch of the plurality of reflection electrode fingers arranged along the first direction is represented by Pr; and
an IDT-reflector gap in the first direction between a center of an electrode finger that is closest to the reflector among the plurality of electrode fingers and a center of a reflection electrode finger that is closest to the IDT electrode among the plurality of reflection electrode fingers is represented by G;
a thickness of the piezoelectric layer is smaller than or equal to a value that is about twice Pi;
G is smaller than Pr; and
Pr is greater than Pi.

2. The acoustic wave element according to claim 1, wherein G/Pr is equal to or greater than about 0.55 and smaller than or equal to about 0.88.

3. The acoustic wave element according to claim 1, wherein
the piezoelectric layer includes a first main surface that is one of the two main surfaces and a second main surface that is another one of the two main surfaces;
the IDT electrodes on the two main surfaces of the piezoelectric layer include a first IDT electrode on the first main surface and a second IDT electrode on the second main surface;
the plurality of reflectors include a plurality of first reflectors on two of the outer sides of the first IDT electrode in the first direction and a plurality of second reflectors on two of the outer sides of the second IDT electrode in the first direction;
a first comb-shaped electrode included in the first IDT electrode and a first comb-shaped electrode included in the second IDT electrode are electrically connected; and
a second comb-shaped electrode included in the first IDT electrode and a second comb-shaped electrode included in the second IDT electrode are electrically connected.

4. The acoustic wave element according to claim 3, further comprising:
a high acoustic velocity support substrate in which bulk waves propagate at an acoustic velocity higher than an acoustic velocity of acoustic waves propagating in the piezoelectric layer; and
a low acoustic velocity layer in which bulk waves propagate at an acoustic velocity lower than an acoustic velocity of acoustic waves propagating in the piezoelectric layer, the low acoustic velocity layer being disposed between the high acoustic velocity support substrate and the piezoelectric layer; wherein
the low acoustic velocity layer is provided on the second main surface such that the low acoustic velocity layer covers the second IDT electrode.

5. The acoustic wave element according to claim 4, further comprising a protection film on the first main surface such that the protection film covers the first IDT electrode.

6. An acoustic wave filter device comprising:
the acoustic wave element according to claim 1.

7. A multiplexer comprising:
a plurality of filters including the acoustic wave filter device according to claim 6; wherein
one of input/output terminals of the plurality of filters is connected directly or indirectly to a common terminal; and
at least one of the plurality of filters except for the acoustic wave filter device has a pass band whose frequencies are lower than frequencies of a pass band of the acoustic wave filter device.

8. The acoustic wave element according to claim 1, wherein the IDT electrodes are defined by multilayer structures including multiple metals that are laminated.

9. The acoustic wave element according to claim 4, wherein the low acoustic velocity layer contacts a surface of the high acoustic velocity support substrate.

10. The acoustic wave element according to claim 4, wherein the high acoustic velocity support substrate includes a support substrate and a high acoustic velocity layer laminated on one another.

11. The acoustic wave element according to claim 3, wherein the first IDT electrode and the second IDT electrode are aligned in a vertical direction of the acoustic wave element.

12. The acoustic wave element according to claim 3, wherein an array pitch of the plurality of first reflectors is different from an array pitch of the plurality of second reflectors.
